(19) United States
(12) Patent Application Publication
(10) Pub. No.: US 2025/0301640 A1
(43) Pub. Date: Sep. 25, 2025

(54) 3D MEMORY DEVICE AND MANUFACTURING METHOD THEREOF

(71) Applicant: MACRONIX International Co., Ltd., Hsinchu (TW)

(72) Inventor: Chih-Hsiung Lee, Hsinchu City (TW)

(73) Assignee: MACRONIX International Co., Ltd., Hsinchu (TW)

(21) Appl. No.: 18/608,932

(22) Filed: Mar. 19, 2024

(51) Int. Cl. H10B 43/27; H10B 43/35

(52) U.S. Cl. CPC H10B 43/27; H10B 43/35

(57) ABSTRACT

A 3D memory device including a stacked structure and at least one channel structure is provided. The stacked structure includes a plurality of conductive layers and a plurality of insulating layers alternately stacked. The at least one channel structure penetrates through the stacked structure, wherein the at least one channel structures includes a top portion and a bottom portion. A ratio of a first width of the bottom portion surrounded by one of the plurality of conductive layers to a second width of the top portion surrounded by another one of the plurality of conductive layers is in a range from 0.85 to 0.95. The provided 3D memory device can be a 3D NAND flash memory device with high capacity and high performance. In addition, a manufacturing method of the 3D memory device is also provided.

### BACKGROUND

### Technical Field

The disclosure relates to a three-dimensional (3D) memory device and a manufacturing method thereof.

### Description of Related Art

In order to meet the demand for high storage density, memory cells in memory devices have become smaller and denser. Therefore, the type of memory devices has developed from a two-dimensional (2D) memory device having a planar gate structure to a 3D memory device having a channel structure. However, the 3D memory device having the channel structure still face many challenges.

For example, in the 3D memory device, there is a relatively large difference between the size of the top portion and the size of the bottom portion in the channel structure with a high aspect ratio. Therefore, the operating speed of memory cells in the 3D memory device would be changed in accordance with the location of the channel structure. Also, the 3D memory device have relatively poor reliability.

### SUMMARY

The disclosure provides a 3D memory device having the relatively high reliability.

The 3D memory provided by one embodiment of the disclosure includes a stacked structure and at least one channel structure. The stacked structure includes a plurality of conductive layers and a plurality of insulating layers alternately stacked. The at least one channel structure penetrates from a top surface of the stacked structure to a bottom surface of the stacked structure, wherein the least one channel structure includes a top portion and a bottom portion. A ratio of a first width of the bottom portion of the at least one channel structure surrounded by one of the plurality of conductive layers to a second width of the top portion of the at least one channel structure surrounded by another one of the plurality of conductive layers is in a range from 0.85 to 0.95.

The 3D memory provided by another embodiment of the disclosure includes a stacked structure and a plurality of channel structures. The stacked structure includes a plurality of word lines and a plurality of insulating layers alternately stacked. The plurality of channel structures penetrate through the stacked structure, wherein the plurality of channel structures include a top portion and a bottom portion. A ratio of a first width of the bottom portion of the plurality of channel structures surrounded by one of the plurality of word lines to a second width of the top portion of the plurality of channel structures surrounded by another one of the plurality of word lines is in a range from 0.85 to 0.95.

The disclosure provides a manufacturing method of a 3D memory device, in which the manufactured 3D memory device has the relatively high reliability.

The manufacturing method of the 3D memory provided by one embodiment of the disclosure includes the following steps. Providing a stacked structure layer including a plurality of first insulating layers and a plurality of sacrificial layers alternately stacked. Forming a plurality of channel holes penetrating through the stacked structure layer. Respectively forming a second insulating layer in the plurality of channel holes, wherein a width of the second insulating layer surrounded by the bottommost sacrificial layer is smaller than a width of the second insulating layer surrounded by the topmost sacrificial layer. Respectively forming a channel structure in the plurality of channel holes, wherein the channel structure includes a top portion and a bottom portion. Removing the plurality of sacrificial layers and the second insulating layer adjacent to the plurality of sacrificial layers, to form a plurality of gate trenches, wherein the plurality of gate trenches expose a portion of the channel structure. Respectively forming a conductive layer in the plurality of gate trenches, to form a plurality of the conductive layers. In the manufactured 3D memory device by one embodiment of the disclosure, a ratio of a first width of the bottom portion of the channel structure surrounded by one of the plurality of conductive layers to a second width of the top portion of the channel structure surrounded by another one of the plurality of conductive layers is in a range from 0.85 to 0.95.

Based on the above, in the 3D memory device provided by one embodiment of the disclosure, the ratio of the first width of the bottom portion of the channel structure surrounded by the bottom layer of the plurality of the word lines to the second width of the top portion of the channel structure surrounded by the top layer of the plurality of the word lines is in a range from 0.85 to 0.95. Therefore, the memory cells respectively located at different heights can have substantially the same size, so that they can have similar operating speed when being operated, which makes the 3D memory device provided by the disclosure have the relatively high reliability.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1I are flow diagrams illustrating a manufacturing method of a 3D memory device according to an embodiment of the disclosure.

FIG. 2A shows an enlarged schematic diagram of a region R1 according to FIG. 1D.

FIG. 2B shows an enlarged schematic diagram of a region R2 according to FIG. 1D.

FIG. 3A shows an enlarged schematic diagram of a region R3 according to FIG. 1I.

FIG. 3B shows an enlarged schematic diagram of a region R4 according to FIG. 1I.

FIG. 4A is a partial perspective view of a 3D memory device according to an embodiment of the disclosure.

FIG. 4B is a partial top view of a 3D memory device according to an embodiment of the disclosure.

FIG. 4C is a partial cross-sectional schematic diagram of a driving circuit layer in a 3D memory device according to an embodiment of the disclosure.

FIG. 5A is a partial cross-sectional view of a 3D memory device according to an embodiment of the disclosure.

FIG. 5B is a partial cross-sectional view of a 3D memory device according to another embodiment of the disclosure.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

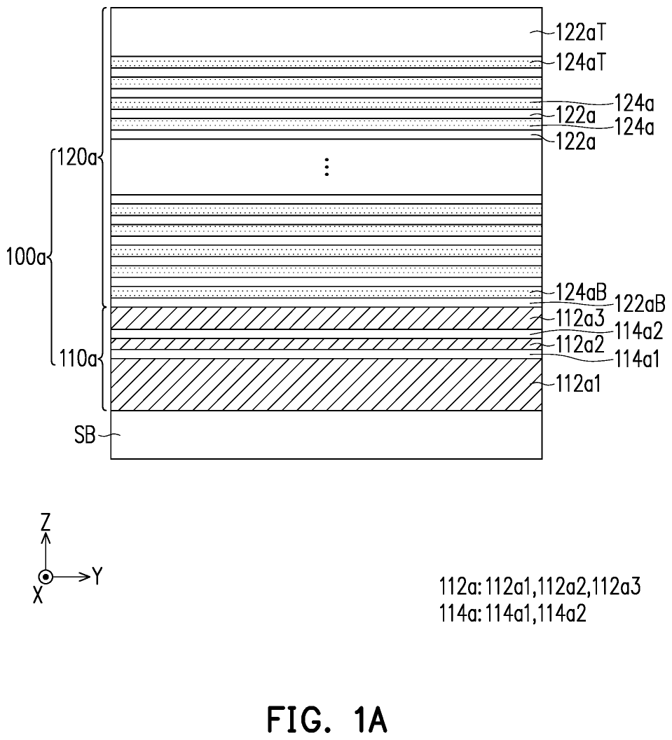

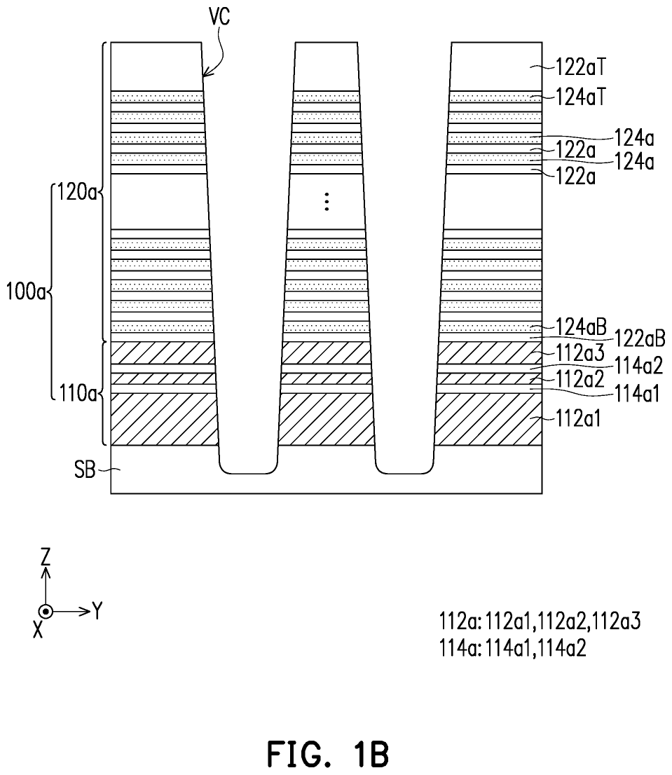

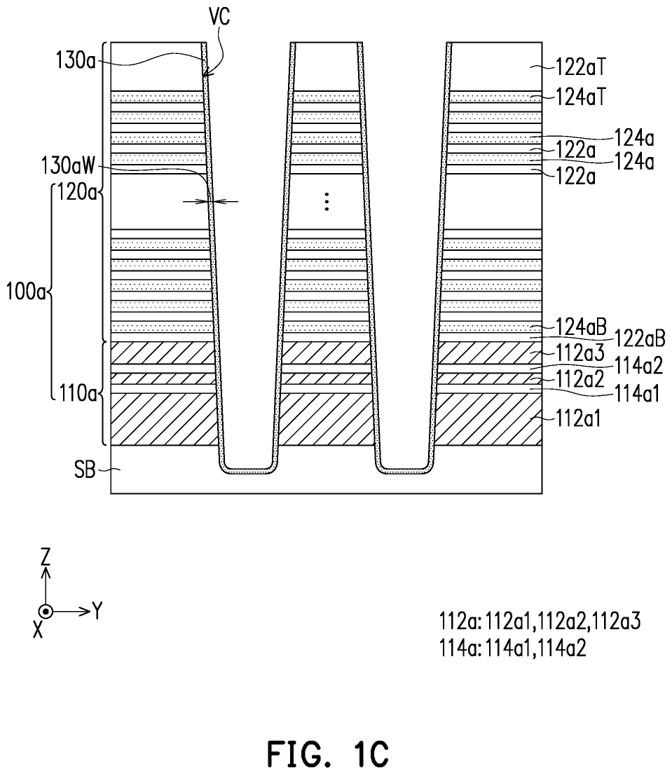

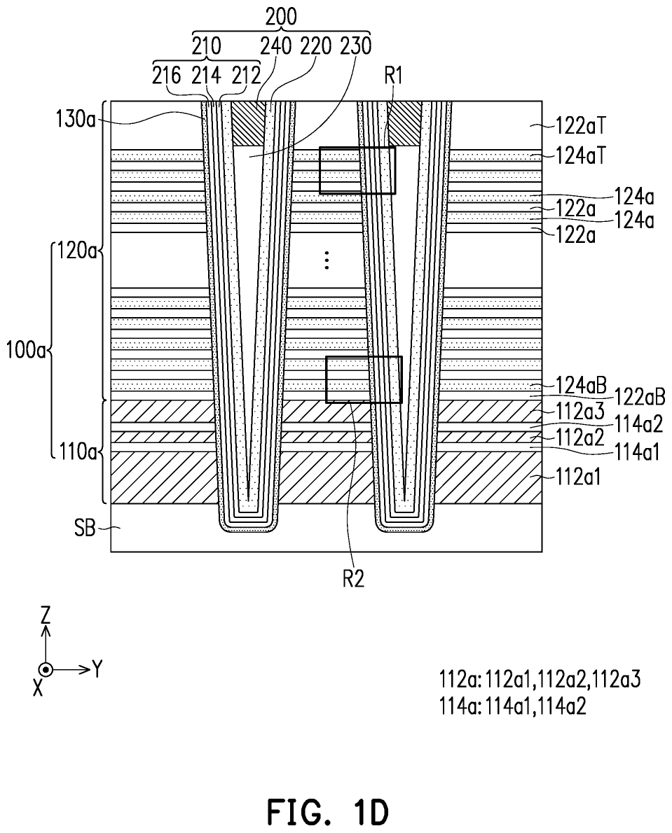

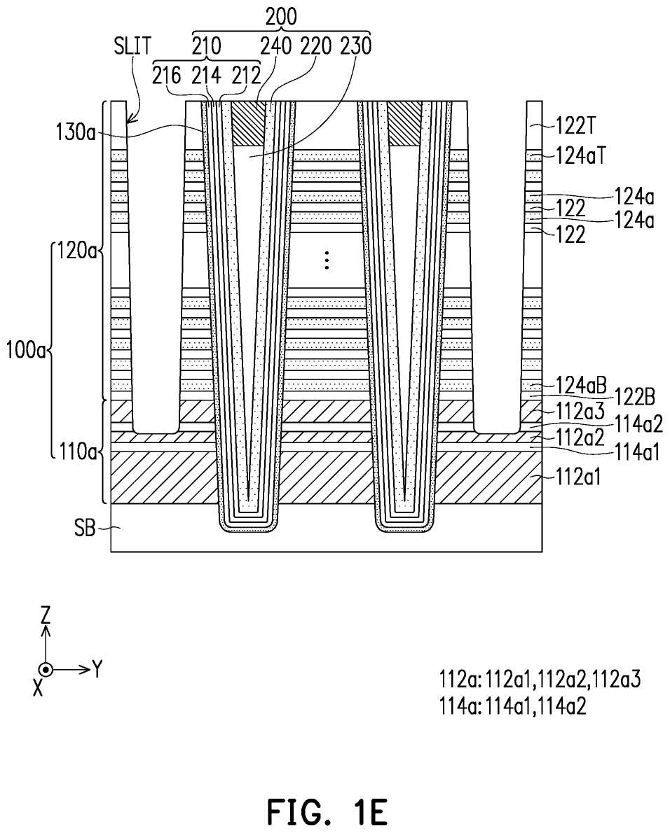

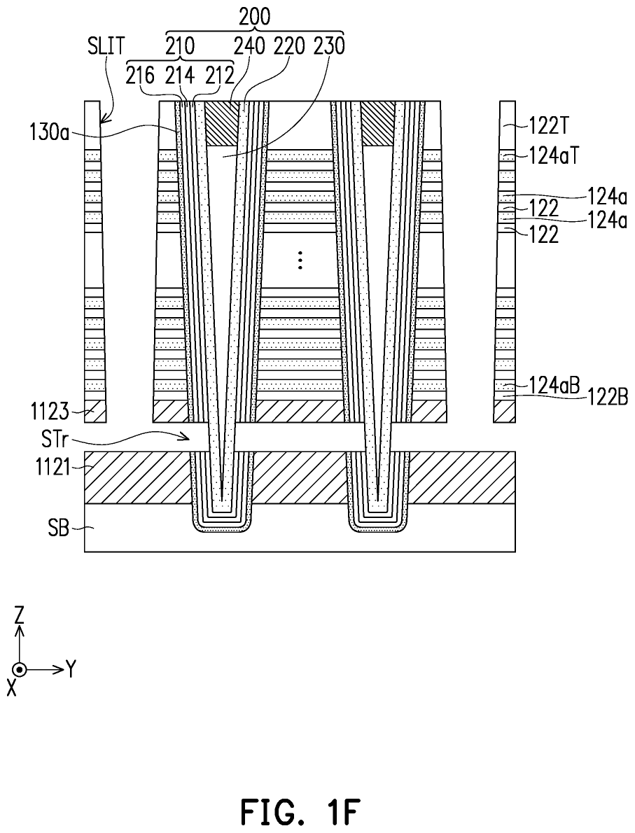

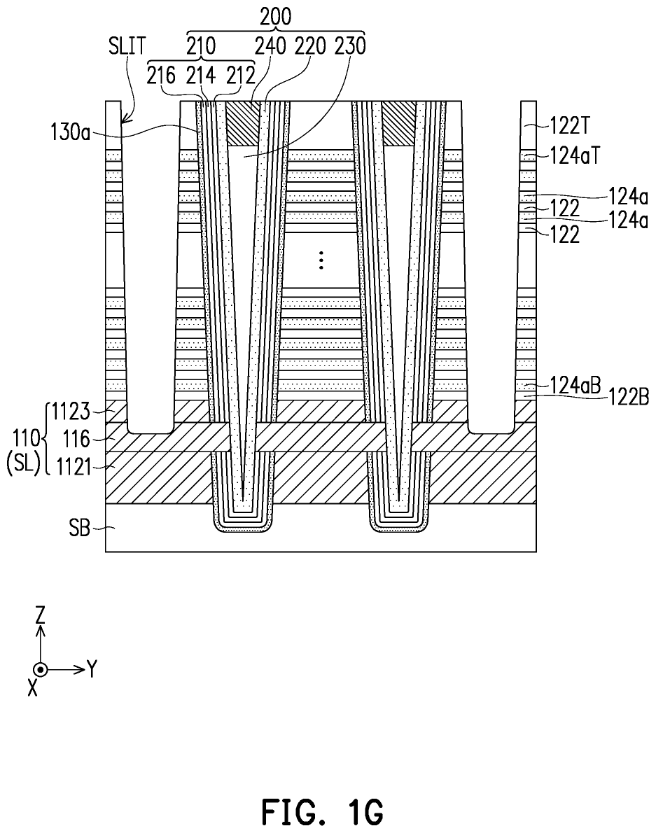

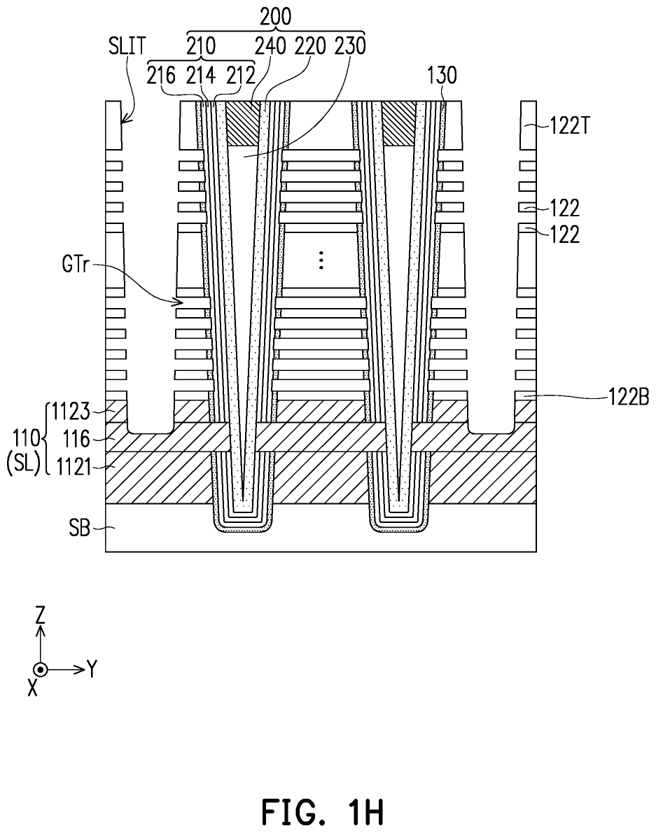

FIGS. 1A to 1I are flow diagrams illustrating a manufacturing method of a 3D memory device according to an embodiment of the disclosure.

Referring to FIG. 1A, providing a stacked structure layer 100a. In some embodiments, the stacked structure layer 100a is disposed above the substrate SB. The substrate SB can be a semiconductor substrate. In some embodiments, a material of the substrate SB can include silicon, doped silicon, germanium, silicon germanium, semiconductor compounds, other suitable semiconductor materials, or combinations thereof. For example, the substrate SB can be a silicon substrate, but the disclosure is not limited thereto. In some embodiments, a plurality of doping regions can be formed in the substrate SB in accordance with the design requirements. For example, the plurality of doping regions including a P-type well region (not shown) and an N-type deep well region (not shown) can be formed in the substrate SB, but the disclosure is not limited thereto. In other embodiments, a buried oxide layer (not shown) can be formed on the substrate SB.

In some embodiments, the stacked structure layer 100a is disposed above the substrate SB. A driving circuit layer can be located between the stacked structure layer 100a and the substrate SB. The structure and function of the driving circuit layer would be described in detail in the following embodiment.

In the present embodiment, the stacked structure layer 100a includes a first stacked structure layer 110a and a second stacked structure layer 120a. The second stacked structure layer 120a is disposed on the first stacked structure layer 110a.

In some embodiments, a method of forming the first stacked structure layer 110a includes the following steps, but the disclosure is not limited thereto. First, a chemical vapor deposition process or other suitable processes is performed to form a conductive layer 112a over the substrate SB. Next, a chemical vapor deposition process or other suitable processes is performed to form an insulating layer 114a on the conductive layer 112a. After that, the above steps are repeated to form a plurality of the conductive layers 112a and a plurality of the insulating layers 114a alternately stacked in a vertical direction Z on the substrate SB. In the present embodiment, the first stacked structure layer 110a includes a conductive layer 112a1, an insulating layer 114a1, a conductive layer 112a2, an insulating layer 114a2, and a conductive layer 112a3 alternately stacked in the vertical direction Z, but the disclosure is not limited thereto. In some embodiments, a material of the conductive layer 112a includes polysilicon, and a material of the insulating layer 114a includes silicon oxide.

In some embodiments, a method of forming the second stacked structure layer 120a includes the following steps, but the disclosure is not limited thereto. First, a chemical vapor deposition process or other suitable processes is performed to form a first insulating layer 122a on the first stacked structure layer 110a. Next, a chemical vapor deposition process or other suitable processes is performed to form a sacrificial layer 124a on the first insulating layer 122a. After that, the above steps are repeated to form a plurality of the first insulating layers 122a and a plurality of the sacrificial layers 124a alternately stacked in the vertical direction Z on the first stacked structure layer 110a. In the present embodiment, the plurality of first insulating layers 122a include a topmost first insulating layer 122aT distal to the first stacked structure layer 110a and a bottommost first insulating layer 122aB proximal to the first stacked structure layer 110a, and the plurality of sacrificial layers 124a include a topmost sacrificial layer 124aT distal to the first stacked structure layer 110a and a bottommost sacrificial layer 124aB proximal to the first stacked structure layer 110a. In some embodiments, a material of the first insulating layer 122a includes silicon oxide, and a material of the sacrificial layer 124a includes silicon nitride. In the present embodiment, a topmost layer of the second stacked structure layer 120a is the topmost first insulating layer 122aT of the plurality of first insulating layers 122a, but the disclosure is not limited thereto.

Referring to FIG. 1B, a plurality of channel holes VC penetrating the stacked structure layer 100a are formed in the vertical direction Z. In detail, in the present embodiment, each channel hole VC penetrates from a top surface of the second stacked structure layer 120a to a bottom surface of the first stacked structure layer 110a in the vertical direction Z. In at least one embodiment, the plurality of channel holes VC may extend into a portion of the substrate SB. In some embodiments, a portion of the stacked structure layer 100a is removed by performing a patterning process to form the plurality of channel holes VC in the stacked structure layer 100a. The patterning process can include a photolithography process and an etching process, but the disclosure is not limited thereto. In at least one embodiment, a portion of the substrate SB is removed.

Referring to FIG. 1C, a second insulating layer 130a is formed in the plurality of channel holes VC. In some embodiments, a method of forming the second insulating layer 130a includes the following steps, but the disclosure is not limited thereto. First, an insulating layer (not shown) is conformally formed on the second stacked structure layer 120a by performing a suitable deposition process. The insulating layer is formed in the plurality of channel holes VC. Next, an etching process is performed to remove the insulating layer located on a top surface of the second stacked structure layer 120a. The remaining insulating layer is conformally disposed in the plurality of channel holes VC to form the second insulation layer 130a. In some embodiments, a material of the second insulating layer 130a includes silicon oxide.

In the present embodiment, a width 130aW of the second insulating layer 130a becomes smaller when getting closer to the bottom of the channel hole VC, and the channel structure 200 to be formed subsequently can have a similar width along the vertical direction Z, which would be described in detail in the following examples.

Referring to FIG. 1D, a channel structure 200 is formed in each of the plurality of channel holes VC. The channel structure 200 includes a charge storage structure 210, a channel layer 220, an insulating pillar 230 and a conductive plug 240. The insulating pillar 230 extends downwards and may be along the vertical direction Z. The conductive plug 240 is disposed on the insulating pillar 230. The channel layer 220 surrounds the insulating pillar 230 and the conductive plug 240. The charge storage structure 210 surrounds the channel layer 220. In some embodiments, a method of forming the channel structure 200 includes the following steps, but the disclosure is not limited thereto.

### Step (1): The Forming of Charge Storage Structure 210

First, a tunneling material layer (not shown), a charge storage material layer (not shown) and a blocking material layer (not shown) are sequentially and conformally formed on the second stacked structure layer 120a by performing a suitable deposition process. The tunneling material layer, the charge storage material layer and the blocking material layer are formed in the plurality of channel holes VC. Next, an etching process is performed to remove the tunneling material layer, the charge storage material layer and the blocking material layer located on the top surface of the second stacked structure layer 120a. The remaining tunneling material layer, and the remaining charge storage material layer and the remaining blocking material layer are conformally disposed in the plurality of channel holes VC. Hence, the charge storage structure 210 including a tunneling layer 212, a charge storage layer 214, and a blocking layer 216 is formed. In some embodiments, the charge storage structure 210 includes a composite layer of oxide-nitride-oxide (ONO). In detail, a material of the tunneling layer 212 may include silicon oxide. A material of the charge storage layer 214 may include silicon nitride. A material of the blocking layer 216 includes silicon oxide, but the disclosure is not limited thereto.

### Step (2): The Forming of Channel Layer 220

First, a channel material layer (not shown) is conformally formed over the second stacked structure layer 120a by performing a suitable deposition process and an annealing process. The channel material layer is formed in each of the plurality of channel holes VC. Next, an etching process is performed to remove the channel material layer located over the top surface of the second stacked structure layer 120a. The remaining channel material layer is conformally disposed in the plurality of channel holes VC, and the channel layer 220 is formed. In some embodiments, a material of the channel layer 220 can include doped semiconductor material or undoped semiconductor material. For example, the material of the channel layer 220 include polysilicon, but the disclosure is not limited thereto.

### Step (3): The Forming of Insulating Pillar 230

First, an insulating material layer (not shown) is formed over the second stacked structure layer 120a by performing a suitable deposition process. The insulating material layer is filled in the plurality of channel holes VC. Next, the insulating material layer located on the top surface of the second stacked structure layer 120a is removed and a portion of the insulating material layer located in each channel hole VC is removed by performing an etch-back process and/or a planarization process. A portion of the channel layer 220 on sidewalls of the channel holes VC is exposed. The insulating pillar 230 is formed in each of the plurality of channel holes VC. In some embodiments, a material of the insulating pillar 230 includes silicon oxide.

### Step (4): The Forming of Conductive Plug 240

First, a conductive plug material layer (not shown) is formed over the second stacked structure layer 120a by performing a suitable deposition process. The conductive plug material layer is filled in the channel holes VC. Next, a planarization process is performed to remove the conductive plug material layer located on the top surface of the second stacked structure layer 120a. Hence, the conductive plug is formed 240 in each of the plurality of channel holes VC. The conductive plug 240 electrically connects to the channel layer 220. In some embodiments, a material of the conductive plug 240 includes polysilicon, metal, or a combination thereof, but the disclosure is not limited thereto.

After the channel structure 200 is formed, the second insulating layer 130a is sandwiched between the channel structure 200 and the stacked structure 100. As stated above, the width 130aW of the second insulating layer 130a becomes smaller when getting closer to the bottom of the channel hole VC.

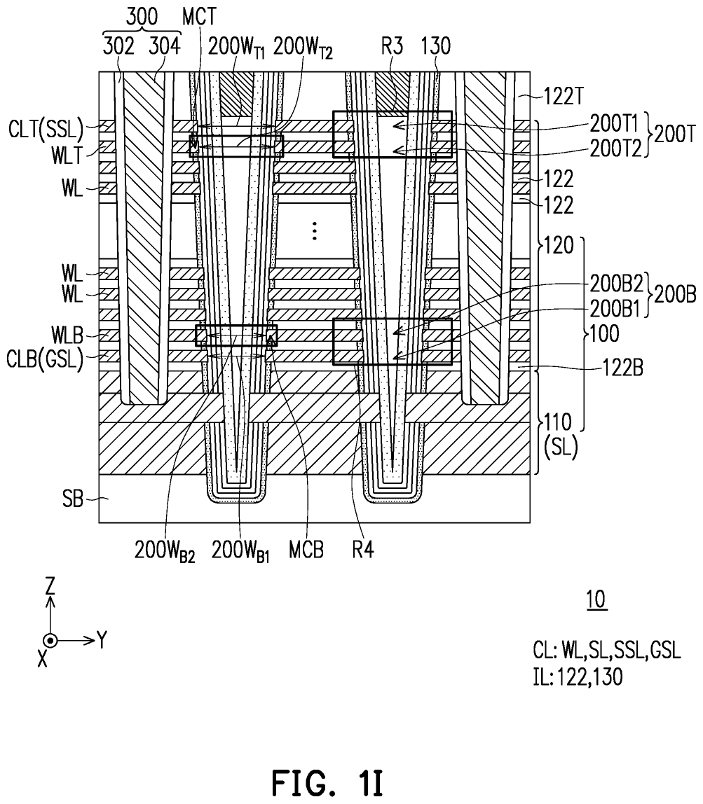

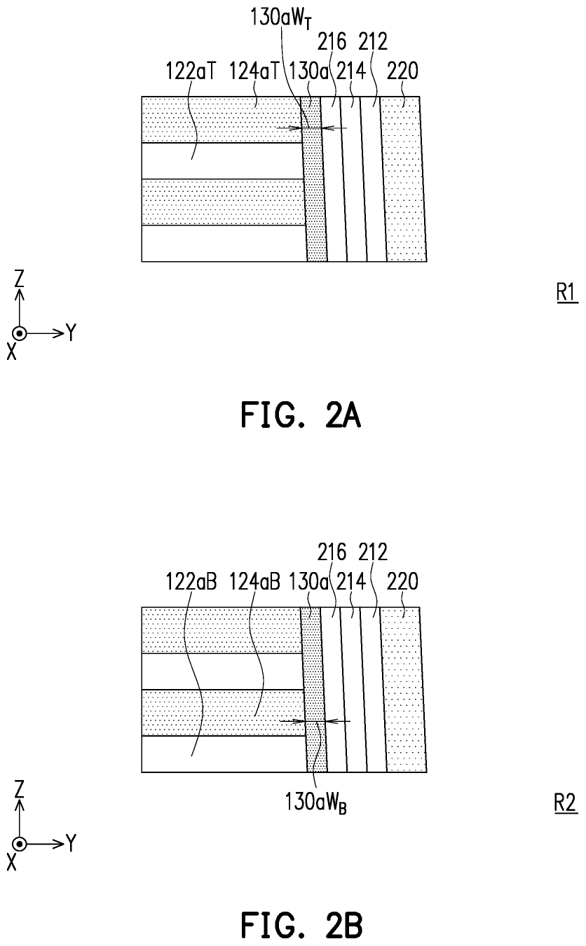

In detail, in the present embodiment as illustrated in FIGS. 2A and 2B, a width 130aW_{B} of the second insulating layer 130a surrounded by the bottommost sacrificial layer 124aB of the plurality of sacrificial layers 124a is smaller than a width 130aW_{T} of the second insulating layer 130a surrounded by the topmost sacrificial layer 124aT of the plurality of sacrificial layers 124a. Referring to FIGS. 2A and 2B, in which regions R1 and R2 respectively illustrate the topmost sacrificial layer 124aT and the bottommost sacrificial layer 124aB of the plurality of sacrificial layers 124a, and the topmost first insulating layer 122aT and the bottommost first insulating layer 122aB of the plurality of first insulating layer 122a. The second insulating layer 130a surrounded by the plurality of sacrificial layers 124a and the plurality of first insulating layers 122a can have different widths along the vertical direction Z. In detail, the second insulating layer 130a have different width 130aW measured in a horizontal direction (including a direction X and a direction Y), and the width 130aW becomes smaller when the second insulating layer 130a gets closer to the bottom of the channel hole VC. In some embodiments, the characteristics of the above second insulating layer 130a can be achieved by controlling the flow rate of the gas during the deposition process, but the disclosure is not limited thereto. In the present embodiment, a ratio of the width 130aW_{B} of the second insulating layer 130a surrounded by the bottommost sacrificial layer 124a_{B} to the width 130aW_{T} of the second insulating layer 130a surrounded by the top sacrificial layer 124aT is in a range from 0.10 to 0.90.

Referring to FIG. 1E, a plurality of slits SLIT are formed in the stacked structure layer 100a. The plurality of slits SLIT extend downwards (may be along the vertical direction Z) in the stacked structure layer 100a and along one horizontal direction (the direction X in the present embodiment). In some embodiments, a portion of the stacked structure layer 100a is removed by performing a patterning process to form the plurality of slits SLIT in the stacked structure layer 100a. The patterning process can include a lithography process and an etching process, but the disclosure is not limited thereto. In the present embodiment, portions of the second stacked structure layer 120a and the first stacked structure layer 110a are sequentially removed by using an etching process. The insulating layer 114a2 in the first stacked structure layer 110a may serve as an etching stop layer. In detail, the etching process can be stopped after the portion of the insulating layer 114a2 is removed, so that the bottom of the plurality of slits SLIT expose a portion of the conductive layer 112a2. In addition, a plurality of first insulating layers 122 are formed after removing the portion of the plurality of first insulating layer 122a in the second stacked structure layer 120a. The plurality of first insulating layers 122 include a topmost first insulating layer 122T and a bottommost first insulating layer 122B.

Referring to FIG. 1F, adjacent to the bottom of the slit SLIT, the insulating layers 114a1 and 114a2 and a portion of the conductive layer 112a in the first stacked structure layer 110a are removed. Also, a portion of the second insulating layer 130a surrounded by the insulating layers 114a1 and 114a2 and the portion of the conductive layer 112a, and a portion of the charge storage structure 210 adjacent to the portion of the second insulating layer 130a in the channel structure 200 are removed to form a lateral source line trench STr. The lateral source line trench STr exposes a portion of the channel layer 220. In detail, after the plurality of slits SLIT is formed, a protective layer (not shown) is formed on a sidewall of each slit SLIT. The protective layer covers sidewalls of the plurality of first insulating layers 122a and the plurality of sacrificial layers 124a in the second stacked structure layer 120a exposed by the slit SLIT. The protective layer also covers the conductive layer 112a3 in the first stacked structure layer 120a exposed by the slit SLIT. After that, an etching process is performed to remove the insulating layer 114a (114a1 and 114a2) and the conductive layer 112a2 in the first stacked structure layer 110a that are not covered by the protective layer and a portion of the charge storage structure 210 in the channel structure 200. After the etching process is performed, the lateral source line trench STr is formed.

It is worth noting that the above etching process can be a multi-stage etching process including the following steps, but the disclosure is not limited thereto.

First, adjacent to the bottom of the slit SLIT, a first wet etching process is performed by using hydrofluoric acid to simultaneously remove the insulating layer 114a2 in the first stacked structure layer 110a, a part of the second insulating layer 130a surrounded by the insulating layers 114a2 and a part of the blocking layer 216 adjacent to the part of the second insulating layer 130a in the channel structure 200. Hence, the first conductive layer 112a2 in the first stacked structure layer 110a and a portion of the charge storage layer 214 in the channel structure 200 are exposed.

Next, adjacent to the bottom of the slit SLIT, a second wet etching process is performed by using phosphoric acid to simultaneously remove the conductive layer 112a2 in the first stacked structure layer 110a and a portion of the charge storage layer 214 in the channel structure 200. Hence, the insulating layer 114a1 in the first stacked structure layer 110a and a portion of the tunneling layer 212 in the channel structure 200 are exposed.

After that, adjacent to the bottom of the slit SLIT, a third wet etching process is performed by using hydrofluoric acid to simultaneously remove the insulating layer 114a1 in the first stacked structure layer 110a, another part of the second insulating layer 130a surrounded by the insulating layers 114a1 and another part of the blocking layer 216 adjacent to the another part of the second insulating layer 130a and a portion of the tunneling layer 212 in the channel structure 200. Hence, an exterior surface of a portion of the channel layer 220 in the channel structure 200, and a top surface of a conductive layer 1121 and a bottom surface of a conductive layer 1123 are exposed by the lateral source line trench STr, respectively.

Referring to FIG. 1G, a source line SL is formed in the lateral source line trench STr. In some embodiments, a method of forming the source line SL includes the following steps, but the disclosure is not limited thereto. First, a conductive layer (not shown) is formed on the second stacked structure layer 120a by performing a suitable deposition process. The conductive layer is filled in the plurality of slits SLIT and the lateral source line trench STr. Next, the conductive layer located on the top surface of the second stacked structure layer 120a and located in the plurality of slits SLIT are removed by performing an etch-back process. Thus, a conductive layer 116 is formed in the lateral source line trench STr. The above etch back process can remove a portion of the conductive layer located in the lateral source line trench STr and exposed by the plurality of slits SLIT, but the disclosure is not limited thereto. In some embodiments, a material of the conductive layer 116 includes polysilicon, metal, or a combination thereof, but the disclosure is not limited thereto. It is worth noting that after the etch back process is performed, the source line SL including the conductive layer 116 located in the lateral source line trench STr and the conductive layer 1121 and the conductive layer 1123 in the first stacked structure layer 110a are formed. In other words, a first stacked structure 110 including the conductive layer 1121, the conductive layer 116 and the conductive layer 1123 is formed.

Referring to FIG. 1H, the plurality of sacrificial layers 124a in the second stacked structure layer 120a and the second insulating layer 130a adjacent to the plurality of sacrificial layers 124a are removed to form a plurality of gate trenches GTr. The second insulating layer 130 is also formed. Each of the plurality of gate trenches GTr exposes a portion of the charge storage structure 210. In detail, an etching process is performed to remove the plurality of sacrificial layers 124a exposed by the plurality of slits SLIT. It is worth noting that an etching liquid used in the etching process not only has high etching selectivity for the plurality of sacrificial layers 124a to the blocking layer 216, but also has high etching selectivity for the second insulating layer 130a to the blocking layer 216. Therefore, at least a portion of the second insulating layer 130a adjacent to the plurality of sacrificial layers 124a is also removed during the etching process, to form the plurality of gate trenches GTr. In the present embodiment, the above etching process is a wet etching process using phosphoric acid as the etching liquid, but the disclosure is not limited thereto.

In the present embodiment, the etching selectivity of the second insulating layer 130a to the blocking layer 216 of the charge storage structure 210 is in a range from 2 to 10 during the above etching process. Therefore, most of the blocking layer 216 is remained during the above etching process.

Referring to FIG. 1I, the conductive layer CL is formed in the plurality of gate trenches GTr, to form a second stacked structure 120. In some embodiments, a method of forming the conductive layer CL includes the following steps, but the disclosure is not limited thereto. First, a conductive layer (not shown) is formed by performing a suitable deposition process. The conductive layer is filled in the plurality of slits SLIT and the plurality of gate trenches GTr. Next, an etch-back process is performed to remove the conductive layer located in the plurality of slits SLIT to form a plurality of the conductive layers CL in the plurality of gate trenches GTr. Also, the second stacked structure 120 is formed. In some embodiments, a material of the conductive layer CL includes polysilicon, metal, or a combination thereof, but the disclosure is not limited thereto. In other words, a second stacked structure 120 including a plurality of alternating conductive layer CL and the first insulating layers 122 is formed.

In the present embodiment, the plurality of conductive layers CL may include a plurality of word lines WL, a string select line SSL and a ground select line GSL. The plurality of word lines WL are stacked in the vertical direction Z and located between the string select line SSL and the ground select line GSL. It is worth noting that FIG. 1I shows the plurality of conductive layers CL includes one string select line SSL and one ground select line GSL, but the present disclosure is not limited thereto. Based on the above, after the plurality of conductive layers CL is formed, memory cells can be defined by the channel structure 200 surrounded by the plurality of word lines WL. For example, FIG. 1I shows that a memory cell MCT and a memory cell MCB can be respectively defined by a topmost word line layer WLT and a bottommost word line layer WLB in the plurality of word lines WL surrounding the channel structure 200, but the disclosure is not limited thereto. In addition, a string select transistor (not shown) and a ground select transistor (not shown) can be respectively defined by the string select line SSL and the ground select line GSL surrounding the channel structure 200.

Since the width 130W of the second insulating layer 130 become smaller when getting closer to the bottom of the channel hole VC, the remaining space of the channel hole VC have a cuboid-like shape. Namely, the channel structure 200 can have similar widths in the vertical direction Z. Therefore, in the present embodiment, a difference between the size of a top portion 200T and the size of a bottom portion 200B in the channel structure 200 can be reduced. Namely, although the channel hole VC has a relatively high aspect ratio, the plurality of memory cells located at different heights can have substantially the same size.

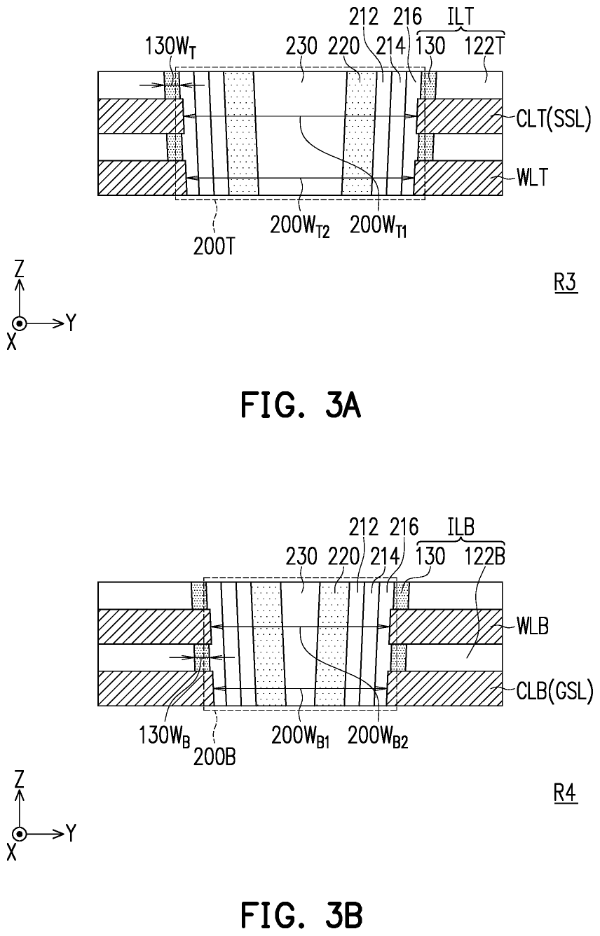

Referring to FIG. 3A and FIG. 3B, in which regions R3 and R4 respectively illustrate a topmost conductive layer CLT and a bottommost conductive layer CLB in the plurality of conductive layers CL and the topmost first insulating layer 122T and the bottommost first insulating layer 122B in the plurality of first insulating layers 122. In detail, in the present embodiment, a ratio of a width 200W_{B1} of the bottom portion 200B1 of the channel structure 200 surrounded by the bottommost conductive layer CLB of the conductive layers CL to a width 200W_{T1} of the top portion 200T1 of the channel structure 200 surrounded by the topmost conductive layer CLT of the plurality of conductive layers CL is in a range from 0.85 to 0.95.

Referring to FIG. 3A and FIG. 3B again, in which regions R3 and R4 further illustrate the topmost word line layer WLT and the bottommost word line layer WLB in the plurality of word lines WL. The channel structures 200 surrounded by the plurality of word lines WL can have similar width along the vertical direction Z. In detail, in the present embodiment, a ratio of a width 200W_{B2} of the bottom portion 200_{B2} of the channel structure 200 surrounded by the bottommost word line layer WLB of the plurality of word lines WL to a width 200W_{T2} of the top portion 200T2 of the channel structure 200 surrounded by the topmost word line layer WLT of the plurality of word lines WL is in a range from 0.85 to 0.95. Based on the above, the plurality of memory cells located at different heights can have substantially the same size, so that they can have similar operating speed when being operated. For example, the memory cell MCT and the memory cell MCB that are farthest apart from each other in the vertical direction Z have similar writing speeds and/or erasing speeds when being operated.

Referring to FIG. 1I again, a plurality of separation structures 300 are formed in the plurality of slits SLIT. In some embodiments, a method of forming the separation structure 300 includes the following steps, but the disclosure is not limited thereto. First, an insulating layer 302 is respectively formed on the sidewalls of each of the plurality of slits SLIT by performing a suitable deposition process. Next, a suitable deposition process is performed to respectively fill a source line contact windows 304 in the plurality of slits SLIT, so as to form the separation structure 300. The insulating layer 302 is used to electrically isolate the source line contact window 304 from the conductive layer CL. The source line contact window 304 is electrically connected to the source line SL. In some embodiments, a material of the insulating layer 302 includes silicon oxide, and a material of the source line contact window 304 includes polysilicon, metal, or a combination thereof, but the disclosure is not limited thereto. In the present embodiment, each separation structure 300 extends laterally (may be along the direction X), and two adjacent separation structures 300 can be used to define one memory block 10B, but the disclosure is not limited thereto.

At this point, the fabrication of the 3D memory device 10 is completed. Although the manufacturing method of the 3D memory device 10 of the present embodiment is explained by taking the above method as an example, the manufacturing method of the 3D memory device provided by the disclosure is not limited thereto.

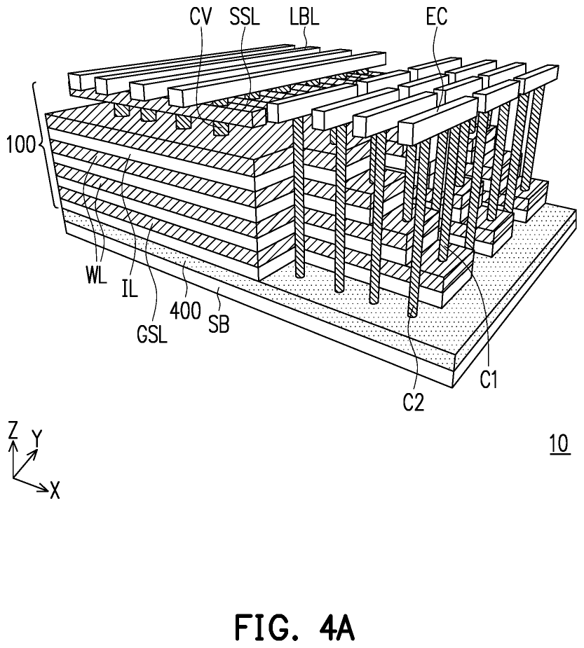

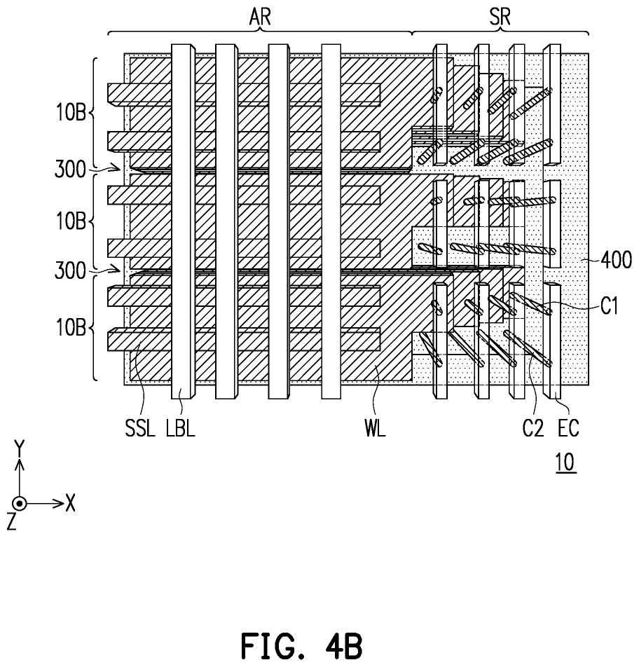

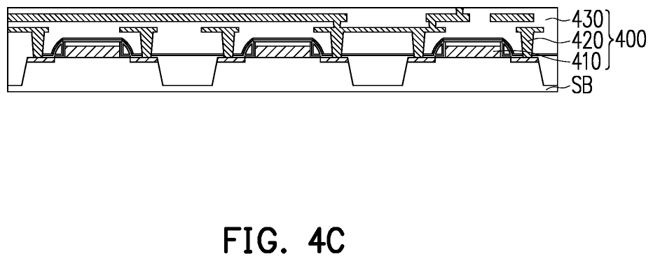

FIG. 4A is a partial perspective view of a 3D memory device according to an embodiment of the disclosure, FIG. 4B is a partial top view of a 3D memory device according to an embodiment of the disclosure, and FIG. 4C is a partial cross-sectional schematic diagram of a driving circuit layer in a 3D memory device according to an embodiment of the disclosure. It should be noted that the embodiment of FIGS. 4A-4C can respectively use the reference numbers and portions of the content of the above embodiments, the same or similar reference numbers are used to represent the same or similar elements, and descriptions of the same technical contents are omitted.

Referring to FIG. 1I, FIG. 4A and FIG. 4B, the 3D memory device 10 provided by the disclosure can be a 3D NAND flash memory, but the disclosure is not limited thereto. The 3D memory device 10 includes a plurality of memory blocks 10B. It is worth noting that FIG. 4A and FIG. 4B only show that the 3D memory device 10 includes three memory blocks 10B as an example, but the disclosure is not limited thereto.

In some embodiments, one of the plurality of memory blocks 10B include a stacked structure 100 and at least one channel structure 200. The plurality of memory blocks 10B are defined by a plurality of separation structures 300. However, the disclosure is not limited thereto.

The plurality of separation structures 300 are disposed on the substrate SB. In some embodiments, the plurality of separation structures 300 can extend in the direction X and can be used to define the plurality of memory blocks 10B of the 3D memory device 10. For example, as shown in FIG. 4A and FIG. 4B, two adjacent separation structures 300 are used to define one memory block 10B, but the disclosure is not limited thereto.

As shown in FIG. 1I, the stacked structure 100 in the 3D memory device 10 includes a first stacked structure 110 and a second stacked structure 120. The second stacked structure 120 is disposed on the first stacked structure 110.

The first stacked structure 110 includes a conductive layer 1121, a conductive layer 116 and a conductive layer 1123 stacked in the vertical direction Z. In the present embodiment, the conductive layer 1121, the conductive layer 116 and the conductive layer 1123 are serve as a source line SL of the 3D memory device 10. The materials of the conductive layer 1121, the conductive layer 116 and the conductive layer 1123 can refer to the above embodiments, and descriptions of the same technical contents are omitted.

The second stacked structure 120 includes a plurality of conductive layers CL and a plurality of insulating layers IL alternately stacked in the vertical direction Z. The plurality of conductive layers CL can each extend on a plane defined by a direction X and a direction Y, which are orthogonal to the vertical direction Z. In the present embodiment, a length of each conductive layers CL in the direction X becomes smaller when getting closer to the substrate SB along the vertical direction Z, so that the plurality of conductive layers CL can be formed to have a ladder structure. The materials and structures of the plurality of conductive layers CL can refer to the above embodiments, and descriptions of the same technical contents are omitted.

One of the plurality of insulating layer IL includes a first insulating layer 122 and a second insulating layer 130. The second insulating layer 130 is located between the first insulating layer 122 and at least one channel structure 200. The first insulating layer 122 and the second insulating layer 130 extend laterally away from the at least one channel structure 200 and overlies a portion of the underlying conductive layer in the plurality of conductive layers CL. For example, the first insulating layer 122 and the second insulating layer 130 extend along a horizontal direction (including the direction X and the direction Y), and cover a portion of the underlying word line in the plurality of word lines WL. The materials of the plurality of insulating layers IL can refer to the above embodiments, and descriptions of the same technical contents are omitted. In the present embodiment, the first insulating layer 122 and the second insulating layer 130 include the same material, but the disclosure is not limited thereto.

In the present embodiment, a width 130W_{T} of the second insulating layer 130 adjacent to a top portion 200T of the at least one channel structure 200 is greater than a width 130W_{B} of the second insulating layer 130 adjacent to a bottom portion 200B of the at least one channel structure 200. Namely, the width 130W of the second insulating layer 130a becomes smaller when getting closer to the bottom of the channel structure 200.

In detail, referring to FIG. 3A and FIG. 3B, in which regions R3 and R4 respectively illustrate the topmost insulating layer ILT and the bottommost insulating layer ILB in the plurality of insulating layers IL. The width 130W_{T} of the second insulating layer 130 in the topmost insulating layer ILT of the plurality of insulating layers IL is greater than the width 130W_{B} of the second insulating layer 130 in the bottommost insulating layer ILB of the plurality of insulating layers IL. In the present embodiment, a ratio of the width 130W_{B} of the second insulating layer 130 in the bottommost insulating layer ILB of the plurality of insulating layers IL to the width 130W_{T} of the second insulating layer 130 in the topmost insulating layer ILT of the plurality of insulating layers IL is in a range from 0.10 to 0.90.

The at least one channel structure 200 extends downwards (may be in the vertical direction Z) and penetrates through the stacked structure 100. Namely, the at least one channel structure 200 penetrates from a top surface of the stacked structure 100 to a bottom surface of the stacked structure 100. The at least one channel structure 200 includes a memory cell string. Each memory cell in the memory cell string is electrically connected to the corresponding word line WL, but the disclosure is not limited thereto. In the present embodiment, each of the at least one channel structure 200 includes a charge storage structure 210, a channel layer 220, an insulating pillar 230 and a conductive plug 240, but the disclosure is not limited thereto.

The charge storage structure 210 surrounds the channel layer 220, which can be an external structure of the channel structure 200. In some embodiments, the charge storage structure 210 can include a composite layer. The charge storage structure 210 includes three dielectric layers sequentially stacked on the side surface of the channel layer 220. For example, the charge storage structure 210 includes a composite layer of oxide-nitride-oxide (ONO), but the disclosure is not limited thereto. In other embodiments, the charge storage structure 210 can include a composite layer of oxide-nitride-oxide-nitride-oxide (ONONO) or a composite layer including other structures. In the present embodiment, the charge storage structure 210 includes a tunneling layer 212, a charge storage layer 214, and a blocking layer 216 surrounding the channel layer 220 in this sequence. The materials of each of the tunneling layer 212, the charge storage layer 214 and the blocking layer 216 can refer to the above embodiments, and descriptions of the same technical contents are omitted.

Based on the above, a plurality of memory cells can each be defined by the channel structure 200 surrounded by the plurality of word lines WL. For example, a memory cell MCT and a memory cell MCB shown in FIG. 1I are respectively defined by the topmost word line layer WLT and the bottommost word line layer WLB in the plurality of word lines WL surrounding the channel structure 200. In some embodiments, the plurality of memory cells can perform 1-bit operations or 2-bit operations through different operation methods. For example, when a voltage is applied to the channel structure 200, electrons can be transported along the channel layer 220 and stored in the charge storage structure 210. The plurality of memory cells can be operated in the single-level cell (SLC; 1 bit) mode or the multi-level cell (MLC; greater than or equal to 2 bits) mode, but the disclosure is not limited thereto.

The channel layer 220 has a ring structure in the vertical direction Z. The materials of the channel layer 220 can refer to the above embodiments, and descriptions of the same technical contents are omitted.

The insulating pillar 230 is surrounded by the channel layer 220. Namely, the insulating pillar 230 is disposed inside the channel layer 220, and extends downwards (may be in the vertical direction Z). The materials of the insulating pillar 230 can refer to the above embodiments, and descriptions of the same technical contents are omitted.

The conductive plug 240 is disposed over the insulating pillar 230 and is also surrounded by the channel layer 220. In some embodiments, the conductive plug 240 is electrically connected to the channel layer 220. The materials of the conductive plug 240 can refer to the above embodiments, and descriptions of the same technical contents are omitted.

In some embodiments, the channel structures 200 surrounded by the plurality of conductive layers CL have similar widths to each other in the vertical direction Z. In detail, the channel structure 200 includes a top portion 200T1 and a bottom portion 200B1. The top portion 200T1 is a portion surrounded by the topmost conductive layer CLT (the string select line SSL in the present embodiment) of the plurality of conductive layers CL, and the bottom portion 200B1 is a portion surrounded by the bottommost conductive layer CLB (the ground select line GSL in the present embodiment) of the plurality of conductive layers CL. In some embodiments, a ratio of a width 200W_{B1} of the bottom portion 200B1 of the channel structure 200 surrounded by the ground select line GSL to a width 200W_{T1} of the top portion 200T1 of the channel structure 200 surrounded by the string select line SSL is in a range from 0.85 to 0.95.

Furthermore, in the present embodiment, the channel structures 200 surrounded by the plurality of word lines WL have similar widths to each other in the vertical direction Z. In detail, the channel structure 200 further includes a top portion 200T2 and a bottom portion 200B2. The top portion 200T2 is a portion surrounded by at least one top layer of the plurality of word lines WL, and the bottom portion 200B2 is a portion surrounded by at least one top layer of the plurality of word lines WL. In the present embodiment, the top portion 200T2 is a portion surrounded by the topmost word line layer WLT of the plurality of word lines WL, and the bottom portion 200B2 is a portion surrounded by the bottommost word line layer WLB of the plurality of word lines WL. In the present embodiment, a ratio of a width 200W_{B2} of the bottom portion 200B2 of the channel structure 200 surrounded by the bottommost word line layer WLB to a width 200W_{T2} of the top portion 200T2 of the channel structure 200 surrounded by the topmost word line layer WLT is in a range from 0.85 to 0.95. Based on the above, the plurality of memory cells located at different heights can have substantially the same size, so that they can have similar operating speed when being operated. For example, the memory cell MCT and the memory cell MCB that are farthest apart from each other in the vertical direction Z have similar writing speeds and/or erasing speeds when being operated.

Referring to FIG. 4A and FIG. 4B, the 3D memory device 10 have an array region AR and a step region SR, and the above channel structure 200 is disposed in the array region AR. The arrangement of the step region SR can be used to electrically connect the components (such as the plurality of memory cells) located in the array region AR to a driving circuit layer 400. Specifically, in the present embodiment, the 3D memory element 10 further includes the driving circuit layer 400, a plurality of contact windows C1, a plurality of contact windows C2, and a plurality of electrical contacts EC.

The driving circuit layer 400 is disposed between the stacked structure 100 and the substrate SB. Referring to FIG. 4C, in the present embodiment, the driving circuit layer 400 includes a plurality of transistors 410, a plurality of conductive wires 420 and a plurality of insulating layers 430. The plurality of transistors 410 can be complementary metal oxide semiconductor field effect transistors (CMOS). Therefore, the architecture of the 3D memory device 10 shown in the present embodiment can be a CMOS under array (CUA) architecture; however, the disclosure is not limited thereto. In some embodiments, the plurality of transistors 410 can be electrically connected to the plurality of word lines WL through the plurality of conductive wires 420 to control the corresponding word lines WL. In detail, the driving circuit layer 400 can include a word line decoder (not shown) composed of the plurality of transistors 410. The word line decoder can be electrically connected to the corresponding memory cells through the corresponding word lines WL. In some embodiments, the word line decoder is configured to operate under the control of control logic (not shown). For example, the word line decoder receives a word line address data from external sources through the control logic. The word line decoder is used to decode the word line address, to apply a voltage provided from a voltage generator (not shown) to the corresponding word lines WL in accordance with the decoded word line address. The plurality of insulating layers 430 can be used to electrically isolate the corresponding plurality of conductive wires 420 from each other and/or electrically isolate the corresponding transistors 410 and the conductive wires 420 from each other.

The plurality of contact windows C1 are disposed in the step region SR and extend downwards (may be along the vertical direction Z), and are each electrically connected to the corresponding conductive layers CL. The plurality of contact windows C2 are disposed in the step region SR and extend downwards (may be along the vertical direction Z), and are electrically connected to the driving circuit layer 400. The plurality of electrical contacts EC are disposed in the step region SR and extend laterally (may be along the direction Y), and are each electrically connected to the corresponding contact window C1 and contact window C2. Based on the above, the components (such as the plurality of memory cells) located in the array region AR can be electrically connected to the driving circuit layer 400 through the arrangement of the plurality of contact windows C1, the plurality of contact windows C2, and the plurality of electrical contacts EC.

In the present embodiment, the 3D memory device 10 further includes a plurality of local bit lines LBL.

The plurality of local bit lines LBL are disposed in the array region AR, and extend laterally (may be in the direction Y). In some embodiments, the plurality of local bit lines LBL are respectively disposed on corresponding channel structures 200. It is worth noting that the corresponding local bit line LBL can be electrically connected to the corresponding channel structure 200 through a via CV. The via CV is electrically connected to the conductive plug 240 in the channel structure 200. In some embodiments, a material of the plurality of local bit lines LBL can be the same as or similar to the material of the plurality of word lines WL.

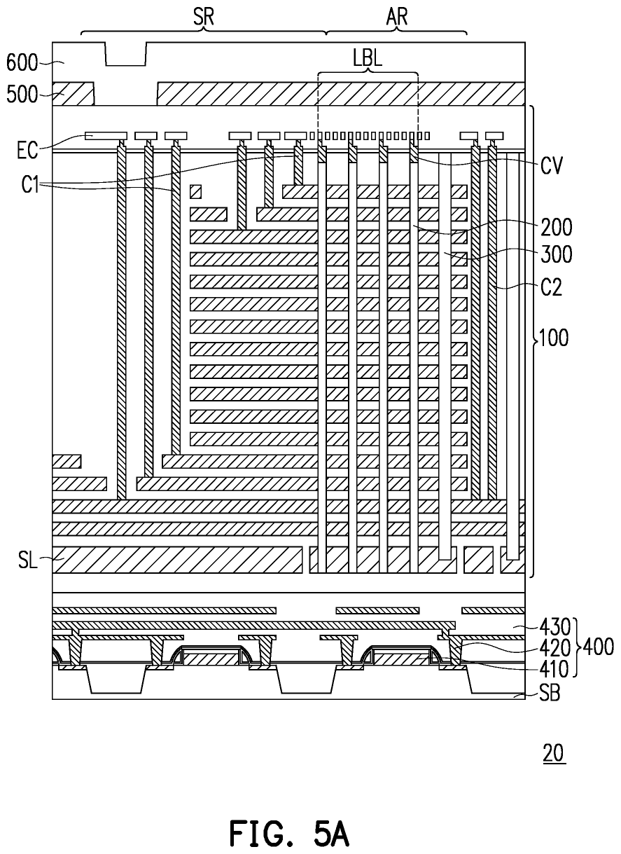

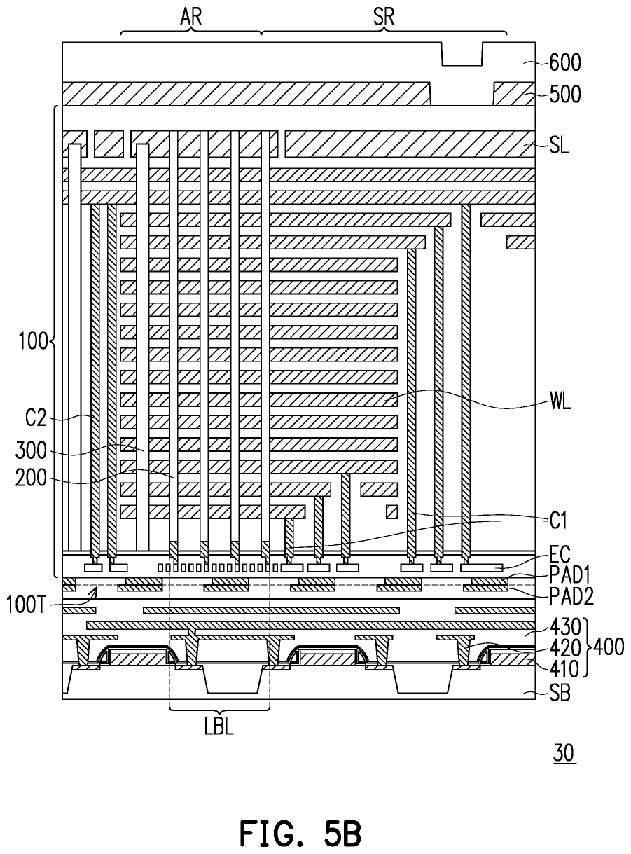

FIG. 5A is a partial cross-sectional view of a 3D memory device according to an embodiment of the disclosure, and FIG. 5B is a partial cross-sectional view of a 3D memory device according to another embodiment of the disclosure.

Referring to FIG. 5A, a 3D memory device 20 has the CUA architecture. The driving circuit layer 400 including the CMOS is formed before the forming of the stacked structure 100. Namely, the CMOS is located under the stacked structure 100, which can be referred to the above embodiments and would be omitted. In the present embodiment, the 3D memory element 20 further includes a conductive layer 500 and an insulating layer 600. The conductive layer 500 is disposed on a top surface of the stacked structure 100. In some embodiments, the conductive layer 500 includes a global bit line, and the global bit line is electrically connected to the corresponding local bit lines LBL, but the disclosure is not limited thereto. The insulating layer 600 is disposed on the top surface of the stacked structure 100 and covers the conductive layer 500. In some embodiments, a material of the conductive layer 500 and a material of the plurality of local bit lines LBL can be the same, and a material of the insulating layer 600 and the material of the plurality of insulating layers IL can be the same.

Referring to FIG. 5B, a 3D memory device 30 has a CMOS bonded Array (CbA) architecture. In detail, a top surface 100T of the stacked structure 100 is provided with a plurality of pads PAD1, and a surface of the driving circuit layer 400 including the CMOS is provided with a plurality of pads PAD2. The plurality of pads pad PAD1 and the plurality of pads PAD2 are bonded to each other. The driving circuit layer 400 including the CMOS is formed before the forming of the stacked structure 100. Namely, the CMOS is bonded to the stacked structure 100. In the present embodiment, the plurality of pads PAD1 are electrically connected to the corresponding electrical contacts EC, and the plurality of pads PAD2 are electrically connected to the corresponding conductive wires 420. Based on the above, the stacked structure 100 and the driving circuit layer 400 can be electrically connected to each other through the pads PAD1 and PAD2. In the present embodiment, the 3D memory device 30 also includes the conductive layer 500 and the insulating layer 600, which can be referred to the above embodiments and would be omitted.

In other embodiments, the 3D memory device of the disclosure can also have a CMOS next to array (CnA) architecture. In detail, the stacked structure 100 and the driving circuit layer 400 including the CMOS are horizontally disposed and are located in adjacent to each other.

In summary, in the 3D memory device provided by the disclosure, the ratio of the first width of the bottom portion of the channel structure surrounded by the bottommost word line layer of the plurality of the word lines to the second width of the top portion of the channel structure surrounded by the topmost word line layer of the plurality of the word lines is in a range from 0.85 to 0.95. Therefore, the memory cells respectively located at different heights can have substantially the same size, so that they can have similar operating speed when being operated. Hence, the 3D memory device provided by the disclosure have the relatively high reliability.

In addition, in the manufacturing method of the 3D memory device provided by the disclosure, the second insulating layer is formed in the plurality of channel holes before forming the channel structure. In addition, the width of the second insulating layer surrounded by the bottommost sacrificial layer is smaller than the width of the second insulating layer surrounded by the topmost sacrificial layer. Based on the above, the difference between the size of the top portion and the size of the bottom portion in the channel structure can be reduced. Although the vertical through hole has a relatively high aspect ratio, the plurality of memory cells located at different heights can have substantially the same size. Hence, they can have similar operating speed when being operated, which makes the 3D memory device provided by the disclosure have the relatively high reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A 3D memory device, including:
a stacked structure, including a plurality of conductive layers and a plurality of insulating layers alternately stacked; and
at least one channel structure, penetrating from a top surface of the stacked structure to a bottom surface of the stacked structure, wherein the least one channel structure includes a top portion and a bottom portion,
wherein a ratio of a first width of the bottom portion of the at least one channel structure surrounded by one of the plurality of conductive layers to a second width of the top portion of the at least one channel structure surrounded by another one of the plurality of conductive layers is in a range from 0.85 to 0.95.

2. The 3D memory device according to claim 1, wherein the first width is disposed at the bottom portion of the at least one channel structure surrounded by the bottommost conductive layer of the plurality of conductive layers.

3. The 3D memory device according to claim 1, wherein the second width is disposed at the top portion of the at least one channel structure surrounded by the topmost conductive layer of the plurality of conductive layers.

4. The 3D memory device according to claim 1, wherein one of the insulating layers includes a first insulating layer and a second insulating layer, and the second insulating layer is located between the first insulating layer and the at least one channel structure.

5. The 3D memory device according to claim 4, wherein the first insulating layer and the second insulating layer include a same material.

6. The 3D memory device according to claim 4, wherein the second insulating layer extends laterally away from the at least one channel structure and overlies a portion of the underlying conductive layer of the plurality of conductive layers.

7. The 3D memory device according to claim 4, wherein a width of the second insulating layer adjacent to the top portion of the at least one channel structure is larger than a width of the second insulating layer adjacent to the bottom portion of the at least one channel structure.

8. The 3D memory device according to claim 1, wherein the at least one channel structure includes:
an insulating pillar, extending downwards through the stacked structure;
a channel layer, surrounding the insulating pillar; and
a charge storage structure, surrounding the channel layer.

9. The 3D memory device according to claim 8, wherein the charge storage structure includes a tunneling layer, a charge storage layer and a blocking layer, and the tunneling layer, the charge storage layer and the blocking layer surround the channel layer in this sequence.

10. The 3D memory device according to claim 1, further including a substrate located under the bottom portion of the at least one channel structure.

11. The 3D memory device according to claim 1, further including a substrate located over the top portion of the at least one channel structure.

12. A 3D memory device, including:
a stacked structure, including a plurality of word lines and a plurality of insulating layers alternately stacked; and
a plurality of channel structures, penetrating through the stacked structure, wherein each of the plurality of channel structures includes a top portion and a bottom portion,
wherein a ratio of a first width of the bottom portion of the plurality of channel structures surrounded by one of the plurality of word lines to a second width of the top portion of the plurality of word lines surrounded by another one of the plurality of word lines is in a range from 0.85 to 0.95.

13. The 3D memory device according to claim 12, wherein the first width is disposed at the bottom portion of the plurality of channel structures surrounded by the bottommost word line layer of the plurality of word lines.

14. The 3D memory device according to claim 12, wherein the second width is disposed at the top portion of the plurality of channel structures surrounded by the topmost word line layer of the plurality of word lines.

15. The 3D memory device according to claim 12, wherein one of the insulating layers includes a first insulating layer and a second insulating layer, and the second insulating layer is located between the first insulating layer and one of the plurality of channel structures.

16. The 3D memory device according to claim 15, wherein a ratio of a width of the second insulating layer in a bottommost insulating layer of the plurality of insulating layers to a width of the second insulating layer in a topmost insulating layer of the plurality of insulating layers is in a range from 0.10 to 0.90.

17. The 3D memory device according to claim 15, wherein the first insulating layer and the second insulating layer include a same material.

18. The 3D memory device according to claim 15, wherein the second insulating layer extends laterally away from the plurality of channel structures and overlies a portion of the underlying word line in the plurality of word lines.

19. The 3D memory device according to claim 12, wherein the at least one channel structure includes:
an insulating pillar, extending downwards through the stacked structure;
a channel layer, surrounding the insulating pillar; and
a charge storage structure, surrounding the channel layer.

20. A manufacturing method of a 3D memory device, including:
providing a stacked structure layer including a plurality of first insulating layers and a plurality of sacrificial layers alternately stacked;
forming a plurality of channel holes penetrating through the stacked structure layer;
respectively forming a second insulating layer in the plurality of channel holes, wherein a width of the second insulating layer surrounded by the bottommost sacrificial layer is smaller than a width of the second insulating layer surrounded by the topmost sacrificial layer;
respectively forming a channel structure in the plurality of channel holes, wherein the channel structure includes a top portion and a bottom portion;
removing the plurality of sacrificial layers and the second insulating layer adjacent to the plurality of sacrificial layers, to form a plurality of gate trenches, wherein the plurality of gate trenches expose a portion of the channel structure; and
respectively forming a conductive layer in the plurality of gate trenches, to form a plurality of the conductive layers,
wherein a ratio of a first width of the bottom portion of the channel structure surrounded by one of the plurality of conductive layers to a second width of the top portion of the channel structure surrounded by another one of the plurality of conductive layers is in a range from 0.85 to 0.95.
